(19) United States
(12) Patent Application Publication
(10) Pub. No.: US 2012/0126433 A1
(43) Pub. Date: May 24, 2012

(54) METHODS AND SYSTEMS FOR FABRICATION OF MEMS CMOS DEVICES IN LOWER NODE DESIGNS

(75) Inventor: Josep Montanya Silvestre, Rubi (ES)

(73) Assignee: Baolab Microsystems SL, Terrassa (ES)

(21) Appl. No.: 13/300,882

(22) Filed: Nov. 21, 2011

Related U.S. Application Data
(60) Provisional application No. 61/415,682, filed on Nov. 19, 2010.

(51) Int. Cl. H01L 29/02; H01L 21/50

(52) U.S. Cl. 257/787; 438/127; 438/50; 257/415; 257/E21.499; 257/E29.002

(57) ABSTRACT

A method for manufacturing an integrated circuit including producing layers that form one or more electrical and/or electronic elements on a semiconductor material substrate. Then, producing ILD layers above the layers forming one or more electrical and/or electronic elements, including the steps of depositing a first layer of etch stopper material, depositing a second layer of dielectric material above and in contact with the first layer, forming at least one track extending through the first and second layers, and filling the at least one track with a non-metallic material.

### CROSS REFERENCE TO RELATED APPLICATIONS

This application claims priority to U.S. Provisional Patent Application No. 61/415,682 filed Nov. 19, 2010, entitled “Methods and Systems for Fabrication of MEMS CMOS Devices,” hereby incorporated by reference in its entirety.

### BACKGROUND

An integrated circuit is a semiconductor device that has a substrate of a semiconductor material on which a series of layers are deposited using photolithographic techniques. The layers are doped, polarized and attacked, so that electrical elements (e.g., resistances, capacitors, or impedances) or electronic elements (e.g., diodes or transistors) are produced. Subsequently other layers are deposited, which form the structure of interconnection layers necessary for electrical connections.

A chip may include a MEMS device and an integrated circuit, where the integrated circuit may control the MEMS. There are various techniques for manufacturing a chip that includes both a MEMS and an integrated circuit. One technique consists of manufacturing one element on top of the other. Another technique consists of joining the two elements (the MEMS and the integrated circuit) on a common substrate according to various means in a multi-chip module (MCM) package. However, proposed processes in the art generally require modification of and additional steps to a standard CMOS fabrication process. Furthermore, existing techniques seem particularly cost-effective, efficient, or suitable for mass or parallel production, as used for chips on a wafer. Existing CMOS MEMS fabrication techniques suffer from limited connections between the MEMS and the integrated circuit, degraded radio frequency properties, poor unit performance, and high cost. Additionally, existing CMOS MEMS typically have an accuracy of approximately 1 micron, and it is very difficult to reduce this precision rate.

In some cases, existing CMOS MEMS fabrication techniques suffer drawbacks when forming MEMS in the back-end layers of an integrated circuit. For example, existing fabrication techniques may be inadequate when fabricating such MEMS in an advanced process, e.g., CMOS Cu process.

Accordingly, there is a need for a more efficient, cost-effective, robust, reliable, scalable, and less disruptive process for fabricating CMOS MEMS devices.

### SUMMARY

The invention addresses deficiencies in the prior art by enabling the fabrication and use of MEMS-based or other integrated chip devices in a more cost-efficient, robust, and scalable manner without the limitations of existing MEMS or other chip-based technologies.

Certain processes disclosed herein address a fundamental technical problem with manufacturing CMOS MEMS devices by enabling formation of a MEMS element within the interconnect layers of a chip using highly reactive etchant gases such as vapor hydrogen fluoride (HF) in a reliably, repeatable, and scalable manner.

While others have developed various CMOS MEMS fabrication techniques, no one has realized a way to robustly and reliably fabricate a CMOS MEMS chip using vapor HF (vHF) to etch the MEMS component within the interconnect layers. Unless the vapor HF etching process is carefully controlled, the etching process is susceptible to a run-away reaction where an excessive portion of a chip is etched and/or the MEMS component is damaged or destroyed. Existing fabrication techniques do not address this problem and existing CMOS MEMS manufacturers have typically avoided using vapor HF for this reason. Typically, current manufacturers use a two-step process of: 1) anisotropic etching of trench outside of the target MEMS location, and then 2) isotropic etching of the Si substrate. Instead of using vapor HF, manufacturers typically use SF6 for line-of-site etching from a trench or hole formed outside of the MEMS location. These existing approaches require a modification of the existing CMOS fabrication process including additional steps to the CMOS process.

By more carefully controlling the vapor HF etching process, the present inventive techniques eliminate the need for additionally and more costly fabrication steps or modifications of the standard CMOS fabrication process. For example, a CMOS chip typically includes an inter level dielectric (ILD) between the silicon substrate and the interconnect layers. To prevent excessive etching of the ILD or silicon substrate, a conductor layer (or conductive metal layer), which is resistant to vapor HF, can be positioned between the ILD and interconnect layers to prevent excessive etching by the vapor HF of the ILD and/or substrate. A conductor layer may be positioned above the MEMS component and include one or more holes, aligned above a MEMS component, that allow for the passage of vapor HF into one or more interconnect layers to effect the release of the MEMS component.

Such techniques may be employed so that the vapor HF is controlled, making the vapor HF etching process within one or more interconnect layers more controllable. Other features and/or techniques may be employed to control the vapor HF etching process. For example, one or more vias may be used to limit and/or confine the vapor HF to a particular region or area of the interconnect layers. A standard vias, which consists of a stacked or segmented vias, cannot effectively block vapor HF from passing through cracks or gaps between its segments. However, the present invention, in certain features, employs a continuous via that is not segmented and, therefore, has no gaps or cracks to allow vapor HF to pass. No one has considered using a continuous via before. In fact, the fabrication of a continuous via is considered a design rule violation by a typical CMOS fabrication foundry. The Applicant, however, has recognized the synergistic effect of combining vapor HF etching in the interconnect layers while controlling such vapor HF etching using a continuous vias to enable a more cost-effective and robust CMOS MEMS fabrication process.

A top layer of the conductor material used to form the CMOS MEMS device may include one or more holes to allow the vapor HF to pass through, while inhibiting other gases or materials to pass through. Instead of having to position a hole or trench outside the area of the MEMS, the present application enables the one or more holes to be aligned above the MEMS because the vapor HF etching process can be controlled. Thus, enabling a more efficient and less intrusive post CMOS fabrication technique for releasing the MEMS as opposed to a two step process where hole must be formed outside the MEMS structure to enable line-of-site etching. More than one top conductor layer may also be used where each layer includes holes that are not aligned vertically. In this arrangement, when the holes are sealed, the offset arrangement of holes between layers inhibits the sealing material from reaching or affecting the MEMS. In an alternative arrangement, a MEMS device may include holes, empty spaces, and/or non moving parts that are aligned with the holes of the top conductor layer such that even if sealing material falls through the holes of the top metal conductor, it does not affect functionality of the MEMS.

Other inventive techniques and/or features may be employed to control the vapor HF etching process in the interconnect layers. For example, using a passivation layer including a layer of silicon rich nitride. A layer of silicon nitride rich in silicon is more resistant to attack with vapor HF. Thus, the layer of silicon nitride rich in silicon leaves less residue on attack with vapor HF. The Si content can be determined by the refractive index (RI) of the layer of silicon nitride. By selectively choosing a passivation layer having an RI in the range of about 1.8 to 2.8, the vapor HF etching process can be controlled, including controlling the duration of vapor HF etching. Depending on the amount of vapor HF etching, excessive residue may be formed that could substantially degrade the performance of the resulting device. Accordingly, the applicant has realized that applying the appropriate temperature for the appropriate period of time, e.g., 110° C., enables the removal of adverse residue from the etching process. Various temperatures over the range of about 100° C. to about 250° C. may be used to enable varying amounts of the residue removal.

The inventive CMOS MEMS vapor HF fabrication process in the interconnect layers may be used to fabricate, without limitation, various devices such as capacitors, mechanical capacitors, inductors, vibrating antennas, sensors, switches, motion sensors, and memory. One type of switch may include a modal switch whereby the transmission of a signal can be controlled by controlling the mode of transmission. For example, a signal transmission system may include a first signal medium arranged to transmit an electrical signal using one of a first transmission mode and a second transmission mode, a second signal medium arranged to transmit an electrical signal using the first transmission mode, and a controller arranged to set the mode of the of the first signal medium to one of the first transmission mode and the second transmission mode.

While various inventive concepts, features, and methods are described as follows, Applicant has contemplated all of the various combinations of dependents steps or features that may be utilized including different combinations of dependent features or steps for a particular aspect (including dependent features or steps listed in the claims), or various combinations of dependent steps or features among and between various aspects (including dependent features or steps listed in the claims). The skilled person will recognize that Applicant has contemplated and provided sufficient disclosure for support of any of the various combinations of features in and among the various aspects.

In one aspect, a MEMS integrated circuit includes a plurality of layers where a portion includes one or more electronic elements on a semiconductor material substrate. The circuit also includes a structure of interconnection layers having a bottom layer of conductor material and a top layer of conductor material where the layers are separated by at least one layer of dielectric material. The circuit further includes a hollow space within the structure of interconnection layers and a MEMS device in communication with the structure of interconnection layers. The at least one bottom layer of conductor material may include a bottom layer of conductor material formed above and in contact with an Inter Level Dielectric (ILD) layer.

In a CMOS fabrication process, the back-end layers of a MEMS device may be complex and highly customizable, with many different types of layers including, e.g., silicon nitride sublayers. Fabricating the MEMS in the back-end layers may require modification, or even requalification, of the standard CMOS fabrication process. Typically, such modifications have been considered costly and inefficient.

Accordingly, the applicant recognized that, the fabrication of a MEMS integrated circuit requires adjustments in the manufacturing process flow. For example, adjustments may be implemented when fabricating MEMS in an advanced standard CMOS fabrication process, such as, without limitation, a CMOS Cu process. In such a process, the back-end layers of a MEMS device may be complex and highly customizable, with many different types of layers including, for example, silicon nitride sublayers or like etch stopper materials. However, to minimize cost and maximize efficiency, the applicant has recognized that certain adjustments can be implemented that do not require requalification of the standard CMOS fabrication process. One such adjustment addresses the formation of gaps or openings in one or more of the silicon nitride sublayers, which enables subsequent efficient formation of one or more hollow spaces within the back-end layers and, thereby, more efficient formation of one or more MEMS components.

The adjustment may include forming a track and/or line in the back-end layers and filing the track with, e.g., silicon oxide, in place of a metal or metallic material. Tracks and/or lines are cavities or voids created in the back-end layers and are typically filled with a metallic material such as aluminum or copper to enable the transfer of electrical information to and from electrical components within the integrated circuit. However, the applicant recognized the advantageous effect of filling a track with a non-metallic material capable of being subsequently removed using, for example, vapor HF. A track and/or line may be formed using an etching process which may include etching one or more dielectric layers including an etch stopper layer. While such an adjustment may be considered a design rule violation, applicant recognized the advantageous effect of implementing the adjustment which avoids the need for deviating substantially from or for requalification of the standard CMOS fabrication process. This process may be applied to dielectric layers at any position in a stack of back-end layers to form gaps or openings in a silicon nitride sublayer included in the dielectric layers.

In one aspect, a method for manufacturing an integrated circuit includes producing layers that form one or more electrical and/or electronic elements on a semiconductor material substrate. The method further includes producing Inter Level Dielectric (ILD) layers above the layers forming the electrical and/or electronic elements by depositing a first layer of etch stopper material and depositing a second layer of dielectric material above and in contact with the first layer. In some features, the method includes depositing a base layer of dielectric material before depositing the first and second layers such that the first layer is above and in contact with the base layer. The method further includes forming at least one track extending through the first and second layers and filling the at least one track with a non-metallic material.

In some features, the method further includes forming at least one hollow space in the ILD layers by applying gaseous HF to at least a portion of the ILD layers including the at least one track. In another configuration, the at least one track includes a channel arranged to hold a metallic material for conducting electrical information to and from the one or more electrical and/or electronic elements. In some features, forming at least one track includes etching the first and second layers. In some embodiments, the first and second layers are etched at substantially the same time using etching such as, without limitation, isotropic etching. In some features, forming the at least one track includes forming the at least one track above a via space. A via space may be empty or hold metal for establishing an electrical connection between elements on the chip. In some configurations, the at least one track defines one or more lateral edges of the first layer that are not in contact with a metallic material. In some embodiments, the metallic material includes at least one of copper and aluminum.

In some configurations, the etch stopper material includes silicon nitride. The dielectric material may include silicon oxide. In some configurations, the non-metallic material is capable of being etched by vapor HF. The non-metallic material may include silicon oxide. In some features, filling the at least one track with a non-metallic material includes a CMOS design rule violation. In some embodiments, the one or more electrical and/or electronic elements have a feature size of 130 nm or lower. In some embodiments, the integrated circuit is manufactured using a CMOS manufacturing process. In some embodiments, filling the at least one track with a non-metallic material is performed without requalification of a conventional CMOS manufacturing process. In some embodiments, the integrated circuit is included in a handheld device such as mobile phone, a portable computing device, a computer tablet, or a wireless computing device. In some embodiments, the integrated circuit is included in a motion sensor. The relatively low cost of the described process may enable widespread usage of such integrated circuits in handheld devices.

In some configurations, at least a portion of a micro-electro-mechanical system (MEMS) is arranged in the integrated circuit. In some embodiments, the portion of the MEMS is arranged in a hollow space in the ILD layers. In some configurations, the MEMS comprises a conductor element including a movable part. In some configurations, the MEMS includes at least two capacitor plates arranged to produce electrostatic fields over the movable part that are capable of moving the movable part. In certain configurations, the MEMS operates as a relay, the MEMS comprising at least two contact points in an electric circuit arranged to allow the movable part to be in contact simultaneously with both contact points. The MEMS may be included in an electrical relay, accelerometer, gyroscope, inclinometer, Coriolis force detector, pressure sensor, microphone, flow rate sensor, temperature sensor, gas sensor, magnetic field sensor, electro-optical device, optical switching matrix, image projector device, analogue connection matrix, electromagnetic signal emission and/or reception device, power supply, DC/DC converter, AC/DC converter, DC/AC converter, A/D converter, D/A converter, and/or a power amplifier.

In another aspect, a chip includes an integrated circuit. The integrated circuit includes layers that form electrical and/or electronic elements on a semiconductor material substrate. The integrated circuit includes Inter Level Dielectric (ILD) layers above the layers forming the electrical and/or electronic elements, including a first layer of etch stopper material and a second layer of dielectric material above and in contact with the first layer. In some features, the integrated circuit includes a base layer of dielectric material below the first and second layers such that the first layer is above and in contact with the base layer. The integrated circuit includes at least one track extending through the first and second layers. The at least one track is filled with a non-metallic material.

In yet another aspect, a method for manufacturing an integrated circuit includes producing layers that form one or more electrical and/or electronic elements on a semiconductor material substrate. The method further includes producing Inter Level Dielectric (ILD) layers above the layers forming the electrical and/or electronic elements by depositing a first layer of etch stopper material and depositing a second layer of dielectric material above and in contact with the first layer. In some features, the method includes depositing a base layer of dielectric material before depositing the first and second layers such that the first layer is above and in contact with the base layer. The method further includes forming a track extending through the first and second layers, the track defining one or more lateral edges of the first layer. The one or more lateral edges are not in contact with a metallic material.

In some features, the method includes filling the track with a non-metallic material. In certain features, the non-metallic material includes silicon oxide. In some features, forming the track includes forming the track above a via space that is empty or holds metal. In certain features, filling the track with a non-metallic material includes a CMOS design rule violation. In some embodiments, the metallic material includes at least one of copper and aluminum. In some features, forming the track includes etching the first and second layers. In some configurations, the etch stopper material includes silicon nitride. The dielectric material may include silicon oxide. In some features, the non-metallic material is capable of being etched by vapor HF. In some configurations, the one or more electrical and/or electronic elements have a minimum feature size of 130 nm or lower. In some configurations, the integrated circuit is included in a handheld device such as mobile phone, a portable computing device, a computer tablet, or a wireless computing device. In some features, the integrated circuit is included in a motion sensor. In some configurations, a micro-electro-mechanical system (MEMS) is arranged in the integrated circuit. The relatively low cost of the described process may enable widespread usage of such integrated circuits in handheld devices.

In yet another aspect, a chip includes an integrated circuit. The integrated circuit further includes layers that form electrical and/or electronic elements on a semiconductor material substrate. The integrated circuit further includes Inter Level Dielectric (ILD) layers above the layers forming the electrical and/or electronic elements, including a first layer of etch stopper material and a second layer of dielectric material above and in contact with the first layer. In some features, the integrated circuit includes a base layer of dielectric material below the first and second layers such that the first layer is above and in contact with the base layer. The integrated circuit further includes a first track extending through the first and second layers. The first track defines one or more lateral edges of the first layer. The one or more lateral edges are not in contact with a metallic material.

### BRIEF DESCRIPTION OF THE DRAWINGS

Other advantages and characteristics of the invention may be appreciated from the following description, which provides a non-limiting description of embodiments of the invention, with reference to the accompanying drawings, in which:

FIG. 1 is a diagrammatical view of a cross section of a first embodiment of a chip according to the invention.

FIG. 2 is a diagrammatical view of a cross section of a second embodiment of a chip according to the invention,

FIG. 3 is the chip of FIG. 2 after the stage of producing a new sealing layer.

FIG. 4 is a diagrammatical view of a cross section of a third embodiment of a chip according to the invention.

FIG. 5 is a diagrammatic view of a cross section of a fourth embodiment of a chip according to the invention, before an HF attack.

FIG. 6 is a diagrammatic view of a cross section of a fourth embodiment of a chip according to the invention, after an HF attack.

FIG. 7 is a diagrammatic view of a cross section of a fifth embodiment of a chip according to the invention, showing an HF attack on a sublayer of silicon oxide being more pronounced than on a sublayer of silicon nitride.

FIG. 8 is a diagrammatic view of a cross section of a fifth embodiment of a chip according to the invention, showing a cantilever break in an uncontrolled way.

FIG. 9 is a diagrammatic view of a cross section of a chip, showing the passivation layer consisting of two different masks according to an illustrative embodiment of the invention.

FIG. 10 is a diagrammatic view of a cross section of a chip showing lack of direct contact between vapor HF and a silicon oxide sublayer due to a wrapping of a silicon nitride sublayer according to an illustrative embodiment of the invention.

FIG. 11 depicts a cross-section after a first set of process flow steps for fabricating a MEMS in a lower node process, according to an illustrative embodiment of the invention.

FIG. 12 depicts a cross-section after a second set of process flow steps for fabricating a MEMS in a lower node process, according to an illustrative embodiment of the invention.

FIG. 13 depicts a cross-section after a third set of process flow steps for fabricating a MEMS in a lower node process, according to an illustrative embodiment of the invention.

FIG. 14 depicts a cross-section after a fourth set of process flow steps for fabricating a MEMS in a lower node process, according to an illustrative embodiment of the invention.

FIG. 15 depicts a cross-section after a fifth set of process flow steps for fabricating a MEMS in a lower node process, according to an illustrative embodiment of the invention.

FIG. 16 depicts a cross-section after a sixth set of process flow steps for fabricating a MEMS in a lower node process, according to an illustrative embodiment of the invention.

FIG. 17 depicts a cross-section after a seventh set of process flow steps for fabricating a MEMS in a lower node process, according to an illustrative embodiment of the invention.

FIG. 18 depicts a cross-section after an eight set of process flow steps for fabricating a MEMS in a lower node process, according to an illustrative embodiment of the invention.

FIG. 19 depicts a cross-section after a ninth set of process flow steps for fabricating a MEMS in a lower node process, according to an illustrative embodiment of the invention.

FIG. 20 depicts a cross-section after a tenth set of process flow steps for fabricating a MEMS in a lower node process, according to an illustrative embodiment of the invention.

### DETAILED DESCRIPTION OF EMBODIMENTS

The application relates to a manufacturing method of a chip comprising a MEMS arranged in an integrated circuit, where the MEMS comprises at least one hollow space. The method comprising:

a) stages for producing layers that form electrical or electronic elements on a substrate made of semiconductor material, and

b) an interconnection stage, in which a structure of interconnection layers is made, which comprises depositing at least one bottom layer of conductor material and one top layer of conductor material separated by at least one layer of dielectric material.

The invention also relates to a chip comprising an integrated circuit, said integrated circuit comprising:

a) layers forming electrical or electronic elements on a substrate of semiconductor material,

b) a structure of interconnection layers, with at least one bottom layer of conductor material and one top layer of conductor material separated by at least one layer of dielectric material.

The invention addresses deficiencies in the prior art using a manufacturing method of a chip of the type indicated in the field of the invention, characterized in that after said interconnection stage b), a stage c) is performed comprising an attack using gaseous HF (hydrogen fluoride), wherein during the attack the hollow space (inter alia) of the MEMS is formed in the structure of interconnection layers.

In fact, this invention is aimed at fully integrating MEMS production in the integrated circuit production. The integrated circuit is produced following the sequence of normal relevant steps, and does not interfere at any time in either the quality or the properties of the integrated circuit's normal manufacturing method. In some embodiments, only one additional step is added.

Therefore, the manufacturing method of the integrated circuit may include an interconnection stage, wherein a plurality of layers of conductor material are deposited. The layers may be made of aluminium, copper, or their alloys such as AlCu, AlSi, or AlCuSi. The layers may further include a titanium or TiN coating. The conductor layers may be separated from one another by layers of inter metal dielectric (IMD) material. The dielectric material may be silicon dioxide or compounds derived from silicon dioxide. In some embodiments, this structure of interconnection layers serves to connect various electrical or electronic components of the integrated circuit, and to establish the necessary contact points to set up the electrical connections with the outside. The different metal layers may be electrically connected using tungsten vias.

The invention proposes availing of this interconnection stage to include, in the actual structure of interconnection layers, the structure consisting of the layers of conductor material and the layers of dielectric material needed to obtain the MEMS. In embodiments where the integrated circuit needs three or more layers of conductor material for its own use, MEMS may be included in the structure of interconnection layers without requiring additional layers. The structure of interconnection layers may comprise two or more layers of conductor material. In some embodiments, including the MEMS in the structure of interconnection layers may require additional layers of conductor or dielectric material. These additional layers may be applied with the same technology and during the same stage as that for the integrated circuit interconnection layers for own use. This allows for the integrated circuit manufacturing method to be qualitatively unaffected due to inclusion of a MEMS in its structure of interconnection layers.

After the interconnection stage, an attack stage using gaseous HF may remove the dielectric material arranged between the layers of conductor material to form hollow space for the MEMS. HF, particularly dry HF, attacks the dielectric material in a very selective way, whereas the layers of conductor material are hardly attacked. HF surrounds the layers of conductor material to create hollows or cavities or produce loose parts.

In some embodiments, chip manufacturing methods comprise a passivation stage to insulate the integrated circuit from the environment and/or ambience, from an electrical and physical-chemical point of view. The stage comprising an attack with gaseous HF may be performed just after the interconnection stage b) and before the passivation stage. This arrangement may be useful as it reduces the process stages. However, in some embodiments, the passivation stage may be performed just after the interconnection stage b), following the standard manufacturing method sequence. The following passivation stages may be performed between interconnection stage b) and HF attack stage c):

B′) a passivation layer (27) production stage, where passivation layer (27) is arranged on the top layer of conductor material, with passivation layer (27) comprising a bottom layer of silicon dioxide and a top layer of silicon nitride, and

B″) a partial passivation layer (27) removal stage.

The HF reaches the dielectric material through the holes made in the passivation layer during the stage of at least partially removing the passivation layer. The stage of at least partially removing the passivation layer may make accessible points of the conductor material required for external electrical connections (with elements outside the chip). In addition, the stage may provide access to the HF to attack and remove dielectric material for producing, inter alia, hollow space or spaces included in the geometrical structure of the MEMS.

In some embodiments, two partial elimination stages of the passivation layer may be performed: in one stage, the passivation may be removed in those areas where it is desired to establish a connection point between one point of a layer of conductor material and the outside (this stage would correspond to a conventional stage), and in the other stage, the passivation may be removed from those areas where it is desired that the HF attack the dielectric material underneath. This prevents the HF from having access to areas on the chip where its effects are not desirable.

In some embodiments, the stage wherein the passivation is removed from those areas where it is desired that the HF attack the dielectric material underneath takes place before stage c) (the stage comprising an HF attack). The stage in which the passivation is removed from those areas where it is desirable to establish a connection point between one point of a layer of conductor material and the outside takes place after stage c).

In certain embodiments, the HF attack is carried out at HF pressures between 5 Torr and 500 Torr. In some embodiments, the HF attack is carried out at pressures between 10 Torr and 150 Torr. A small amount of water or alcohol vapor may be added as a reaction initiator (catalyst). In embodiments using alcohol vapor as the catalyst, the vapor may not be consumed in the reaction. However, the alcohol vapor serves to initiate the attack, and scavenge water vapor that may be generated during the HF attack. This may help avoid a buildup of reactants due to the water vapor. The silicon oxide attack later may result in the production of a sufficient amount of water to be able to keep the reaction running. The process may not need strict temperature control. In some embodiments, the process may be run at a fixed temperature chosen from the range between 15° C. and 50° C.

In some embodiments, a layer may be a continuous, even layer. In some embodiments, a layer may form a certain pattern on the bottom layer, i.e., a layer that partially covers the bottom layer according to a pre-established pattern. The passivation layer comprises a sub layer of silicon oxide and a sub layer of silicon nitride, where the sub layer of silicon nitride may include some minority components, such as oxygen, hydrogen and others.

In some embodiments, in stage b′) of producing a passivation layer, the layer of silicon nitride is a layer of silicon rich nitride. A layer of silicon nitride rich in silicon is more resistant to attack with HF. A layer of silicon nitride rich in silicon leaves less residue on attack with HF. The Si content may be determined via the refractive index (RI) of the layer of silicon nitride. In some embodiments, the nitride areas rich in silicon may have an RI above 2.2. In some embodiments, the nitride areas rich in silicon may have an RI above 2.3. In embodiments with an RI value equivalent to 2.45, the attack is minimal. This may be achieved, for example, by modifying the SiH₄/NH₃ ratio in a PECVD reactor. Conventionally, the layer of silicon nitride may have a refractive index between 1.9 to 2.1.

In some embodiments, the chip is heated to a temperature of 150° C. before stage c) to remove residues prior to stage c). In some embodiments, the chip is heated after stage c). In some embodiments, the chip is heated after stage c) to a temperature higher than the evaporation temperature of the polymer produced from the reaction between the passivation layer and the HF. The attack with HF may leave some residues on metallic surfaces, which may be complex compounds, possibly polymerized, and derived from ammonium fluoride, for example, (NH₄)₂Si(F₆)₈. The residues may be removed by heating the chip above a certain temperature. In some embodiments, a temperature of 110° C. may be used. In some embodiments, a temperature of 170° C. may be used. In some embodiments, a temperature of 180° C. may be used. In embodiments where a temperature of 250° C. is used, the residue may be removed completely.

In some embodiments, the product of the reaction between the passivation layer and the HF, which is at least partially deposited on the metallic surfaces as a residue, may not be a polymer. The residue may be removed by heating the chip to a temperature higher than the evaporation temperature of the residue. The amount of residue after HF attack may be minimized by using a layer of silicon nitride rich in silicon.

In one embodiment, after stage c) an ALD (Atomic Layer Deposition) coating stage is carried out. The ALD coating technique is known in the art and an application thereof is described, for example, in issued U.S. Pat. No. 7,426,067. The ALD coating allows for covering the surfaces of conductor material with materials (for example, other metals) that have particularly interesting properties. In some embodiments, thin (for example, monoatomic), even layers may be deposited. In some embodiments, monoatomic layers may be deposited several times to form a thicker layer. For example, a pulsed process may be used, and a monoatomic layer may be deposited at each pulse. Repeating the process over multiple pulses may allow for the formation of a thicker layer. This way, various improvements may be achieved.

The materials used in the structure of interconnection layers (dielectric material and conductor material) may be selected for optimum result for a conventional integrated circuit. However, MEMS structures may require properties for which these materials are not particularly suitable. For example, hardening properties may be improved by adding a very hard metallic layer on top of the layers of conductor material. The hard metallic layer may be composed of Ru, Pt or ZnO, or alloys thereof. Properties may also be improved to reduce stiction problems.

The layer of conductor material may be coated even when residues from the reaction between the passivation layer and the HF remain on the layer. The ALD coating may recoat the layer of conductor material and the residue arranged thereon, to obtain a new conductor surface (if the ALD coating is conductive) that is very coarse. This coarse surface may be exhibit improved properties that reduce stiction problems.

In order to prevent the ALD coating, when it is deposited on all surfaces (both metallic and dielectric), from causing unwanted short circuits, the ALD coating may be made in a time shorter than the percolation time. When the ALD coating begins, the whole treated surface may not be recoated instantly. Instead “islands”, “bumps”, or formation cores may develop, which broaden during the reaction time until they interconnect together, finally, to the point that they completely recoat the target surface. The time required for the complete coating is the percolation time. If the reaction is interrupted before said percolation time, i.e., before the surface to be treated is totally recoated, a partially recoated surface may be obtained with the said “islands” or “bumps”. These “islands” or “bumps” are suitable as electrical contacts, and no short circuit is caused with other elements on the MEMS device because the “islands” are not interconnected.

In embodiments where the MEMS has a mobile element, the mobile element may be subject to movement during the ALD coating stage. The mobile element may be loose and physically independent. The mobile element released during the HF attack stage c) may be in contact with and supported by the layer underneath it. This makes correctly recoating the bottom surface of the mobile element and the top surface of the layer under the MEMS difficult. Moving the mobile element allows the reagents from the ALD method to reach these surfaces perfectly and the ALD coating to be performed uniformly on all the desired surfaces. In some embodiments, a Self Assembled Monolayer (SAM) coating stage may follow the ALD coating stage. In some embodiments, a SAM coating may be performed instead of the ALD coating. The SAM coating may helpful in reducing stiction.

In some embodiments, and/or, a stage of producing a new passivation layer be carried out (which may be equivalent or different to stage b′)) after the attack stage c). This stage serves to physically close the chip and insulate and protect it from the environment. In some embodiments, this stage may be carried out after the ALD coating stage.

The HF may attack the dielectric material in all directions. This makes possible the creation of cavities, or release mobile elements that are completely loose (deposited on the layer underneath them). An area of the chip that need not be attacked may be protected by covering the area with a layer of conductor material. A layer of dielectric material, underneath a layer of conductor material, may be attacked via a plurality of holes included in the layer of conductor material that are sized such that they allow HF molecules to pass through. However, these holes are small enough that to not allow nitrides to pass through.

In some embodiments, these holes may have a diameter less than or equivalent to 500 nm. In some embodiments, these holes may have a diameter less than or equivalent to 100 nm. Before the stage of producing a new sealing layer takes place, the layer of conductor material with the holes (in some embodiments, the top layer) may undergo an ALD coating. The ALD coating may close the holes which contributes to depositing the new sealing layer satisfactorily, covering all the holes. In some embodiments, the holes have a circular cross section. In some embodiments, the holes may not have a circular cross section. These holes may have a cross section with an area that is smaller or equivalent to the area of a circle with the indicated diameter.

In some embodiments, a layer resistant to HF attack may be added underneath the bottom layer of conductor material. This layer protects the structure of layers forming the electrical or electronic elements from the HF. The interconnection structure may comprise several layers of conductor material (more than two), and some of them (one of the bottom ones) may be used to include a layer of conductor material arranged underneath the MEMS devices. This layer acts as a protection barrier to prevent the HF from reaching the structure of layers forming the electrical or electronic elements. For example, HF may be prevented from reaching the Inter Level Dielectric (ILD) layer, since the ILD layer is attacked quickly by the HF and may produce waste products.

In some embodiments, HF may be prevented from attacking these layers by depositing a very fine layer of amorphous silicon on top of the layers that need protection. In some embodiments, the very fine layer of amorphous silicon is a few nanometers thick.

In some embodiments, a partition of HF resistant material may be added around the MEMS. This partition may extend perpendicular to the substrate and surround the MEMS in a direction parallel to the substrate. The MEMS is surrounded by a partition so that the HF may not spread uncontrollably parallel to the substrate. This may allow determination of the maximum extent of the HF attack, parallel to the substrate. The term “HF resistant material” may be defined as any material that is resistant to gaseous HF, where said gaseous HF is dry. The “dry” HF does not include water or alcohol, although there may be water from the actual HF reaction.

In some embodiments, the HF attack may start with the addition of a certain amount of water or alcohol vapor, which acts as a catalyst for starting the reaction. The rest of the attack may be performed “dry”, whereby no further water or alcohol is added. The reaction generates a certain amount of water enough to maintain the reaction, i.e., it is a self-maintained reaction. In some embodiments, the reaction is controlled (by pressure, temperature control, and the presence of alcohol vapor) to prevent production of an excessive amount of water. Excess water may cause an excessively energetic and uncontrolled attack. The definition of the term “HF resistant material” also includes those materials which are minimally attacked compared to the dielectric material. For example, aluminium and copper are “HF resistant materials”.

In some embodiments, the partition made of HF resistant material may be based on elongated rods of tungsten, similar to rods made conventionally to interconnect different layers of conductor material.

In some embodiments, at least one direct interconnection is established between the substrate and at least one of said metallic layers by means of an HF resistant material. A direct connection anchors the layer of conductor material to the substrate, preventing the structure from collapsing in the event that the HF removes all the dielectric material arranged on top of the layer of conductor material.

In some embodiments, the interconnection material may be a metal. Such embodiments pose a risk of establishing non-desired electrical contacts when interconnecting the layers of conductor material with the substrate (which is also a conductor). A layer of amorphous silicon, which is an insulator, may be inserted between the interconnection and the substrate to mitigate the risk.

In some embodiments, a plurality of layers of conductor material may be deposited in the interconnection stage. In some embodiments, a maximum of six layers of conductor material may be deposited in the interconnection stage. In some embodiments, MEMS devices may require five layers (or less) of conductor material. In some embodiments, MEMS devices may only require three layers of conductor material. In embodiments where the interconnection stage is limited as indicated, the MEMS may be completely integrated in the actual structure of interconnection layers of the integrated circuit, whereby the conventional manufacturing method of the integrated circuit is virtually unaffected.

As already mentioned, the passivation layer usually comprises a sublayer of silicon oxide and a sublayer of silicon nitride. When this passivation layer is attacked, first the silicon nitride is attacked, but once this sublayer is perforated (for example, through the use of patterning), the attack extends to the sublayer of silicon oxide. The sublayer of silicon oxide is attacked more easily than the sublayer of silicon nitride, so that the sublayer of silicon nitride remains in a cantilever arrangement around the attack holes. These cantilever areas are fragile and prone to breaking. To avoid this situation, the two sublayers of the passivation layer may be made with masks that are different to one another. The sublayer of nitride may have some areas where it extends passing completely through the sublayer of oxide, and reaching the layer lying underneath (in some embodiments, a layer of conductor material). If the attack takes place in one of these areas, the hole may be made to form a chimney that passes through the sublayer of nitride without the HF coming into contact with the oxide.

A further aim of the invention is a chip of the type indicated at the beginning characterized in that it comprises, in addition, at least one MEMS arranged in said structure of interconnection layers, where said MEMS comprises at least one hollow space, where at least one part of the hollow space is arranged under a sheet of conductor material belonging to one of the layers of conductor material. “Under” means in the direction towards the substrate. In other words, it is not possible to directly (in a straight line) access the hollow space from the outside (through an opening made in the passivation layer) as the sheet of conductor material is in the way. Therefore, it is not possible to create the hollow space using techniques that attack the dielectric material and are directional, such as for example the techniques that use plasma.

In some embodiments, in addition the chip comprises a passivation layer, where passivation layer is arranged on top of the top layer of conductor material, with passivation layer comprising a bottom layer of silicon dioxide and a top layer of silicon nitride. These layer structures may be superimposed or at least partially superimposed and, may be continuous or homogenous layers. In some embodiments, the layers may form a certain design on the bottom layer, made up of masks.

Micro-electro-mechanisms or micro-electro-mechanical systems (MEMS) are small electro-mechanical devices made using layer deposition technologies based on photolithographic techniques. MEMS may provide cavities or hollow spaces in the inside thereof, which may be filled with liquids or gases. While conventional integrated circuits are completely solid devices, i.e., without any kind of hollows. Hollows may be defined as cavities that are larger than hollows on the atomic or subatomic scale. In some embodiments, MEMS may have mobile elements inside them. The mobile elements may be joined by one of the ends thereof to the rest of the MEMS structure, or may be completely loose (i.e., not physically attached to its surroundings) inside a housing that is at least partially closed (to prevent the loose part from “escaping” from the MEMS).

A MEMS structure like the one described above may be obtained when a sheet of conductor material belonging to one of the layers of conductor material has at least one part of its lower surface (facing the substrate) free of dielectric material. The chip may include any of the characteristics derived from the method according to the invention.

In some embodiments, the MEMS included in the integrated circuit comprises a conductor element as a loose part. Processes and materials (fore example, metals) normally used to manufacture integrated circuits usually suffer from the drawback that they accumulate residual stresses and stress gradients. This drawback may be irrelevant for a conventional integrated circuit. However, in a MEMS, if a cantilever metallic sheet has these accumulations of residual stresses and/or stress gradients, it may become deformed. This deformation may be such that it renders the MEMS useless or, at least, prevents it from working properly. However, if the MEMS operates via parts that are completely loose, it may be easier to compensate or neutralizes the effects caused by said states of stress. Also, while the MEMS is working, temperatures may be high enough to influence the mechanical properties of the metallic sheets forming part of the MEMS. For example, if the metallic sheets are made from aluminium (or one of its alloys), there may be fluency problems with the cantilever sheets. This problem may also be resolved more easily if the MEMS operates via parts that are completely loose.

The MEMS may also include at least two capacitor plates that can generate electrostatic fields over the loose part that are capable of moving said loose part. Document WO 2004/046807 describes a series of these devices, for example on pages 3 to 17 and 19 to 27. Document WO 2004/046807 also describes a series of these devices, as well as documents WO 2005/101442, WO 2005/111759 and WO 2005/112190.

It is particularly advantageous that the MEMS also comprises at least two contact points in an electrical circuit, where the loose part is able to adopt a position wherein it is simultaneously in contact with both contact points, so that an electrical connection can be established between the contact points, whereby the MEMS acts as a relay, particularly like the relays described in document WO 2004/046807, on pages 3 to 12 and 19 to 26.

In some embodiments, the integrated circuit of the chip comprises a MEMS device from the group of MEMS devices made up of electrical relays, accelerometers, gyroscopes, inclinometers, Coriolis force detectors, pressure sensors, microphones, flow rate sensors, temperature sensors, gas sensors, magnetic field sensors, electro-optical devices (particularly the digital, reflector electro-optical devices known as DMD—Digital Micromirror Device), optical switching matrices, image projector devices, analogue connection matrices, electromagnetic signal emission and/or reception devices, power supplies, DC/DC converters, AC/DC converters, DC/AC converters, A/D converters, D/A converters, and power amplifiers.

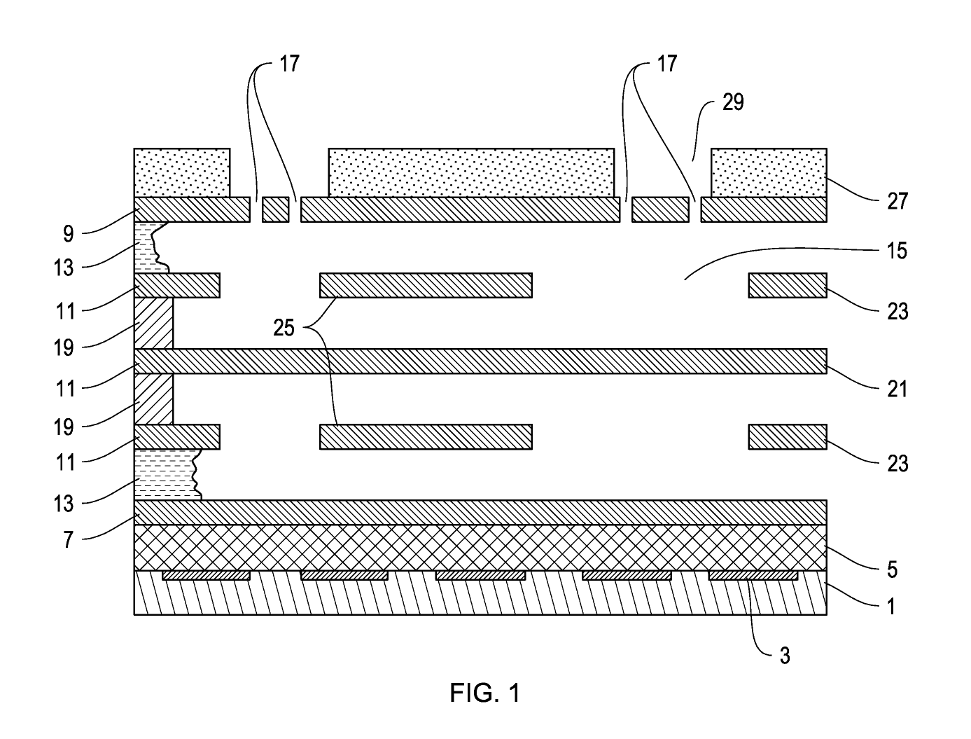

FIG. 1 shows a diagrammatical view of a cross section of a chip according to the invention. The thickness of the layers has been magnified. The cross section shows a MEMS that forms a relay with a cantilever electrode 21, two contact electrodes 23 and two action electrodes 25.

The chip comprises a substrate 1 on which there is a plurality of electronic elements 3, for example transistors. Next there is a layer of borophosphosilicate glass 5 (BPSG). This layer, called the Inter Level Dielectric (ILD) layer, may consist of a layer of doped oxide (for example, BPSG or phosphosilicate glass (PSG)) and a layer on top of non-dopated oxide. The structure of interconnection layers starts on top of the layer of borophosphosilicate glass 5, with one bottom layer of conductor material 7 and one top layer of conductor material 9. Between the bottom layer and the top layer of conductor material 7 and 9, there are three additional layers of conductor material 11 separated from one another by layers of dielectric material 13. The dielectric material has mostly been removed to form the cavity or hollow space 15 which allows the cantilever movement of the electrode 21. FIG. 1 shows, diagrammatically and as an example, the end of two areas of the dielectric material attacked by the HF.

The top layer of conductor material 9 has some holes 17 through which the HF that has attacked the dielectric material may pass. In the case of the cantilever electrode 21 holes have not been included because the HF may skirt around the cantilever electrode 21 so that it may attack the dielectric material lying underneath the said cantilever electrode 21 without the need for said holes. In fact, since the cantilever electrode 21 is relatively narrow (perpendicular to the paper), the HF may skirt around it in the direction of its width.

In the left of FIG. 1 two paths 19 of electrical connection may be seen between layers of conductor material.

In the example in FIG. 1, the MEMS structure starts immediately from the bottom layer of conductor material 7. However, in some embodiments, there may be some additional layers of conductor material between the MEMS and the layer of borophosphosilicate glass 5 to establish a certain electrical connection between the electronic elements 3 provided underneath the MEMS.

The chip is initially closed by a passivation layer 27. During the stage of partially removing passivation layer 27 openings 29 are formed, through which the HF may attack the dielectric material. After attacking with HF, a new passivation layer may be produced that closes openings 29. In some embodiments, a new sealing (for example, Wafer Level Chip Scale Packaging (WLCSP)) may be produced to close openings 29. As the size of holes 17 is small enough, the new sealing layer does not pass through said holes 17. In some embodiments, the removal of the passivation layer 27 is partial or not complete.

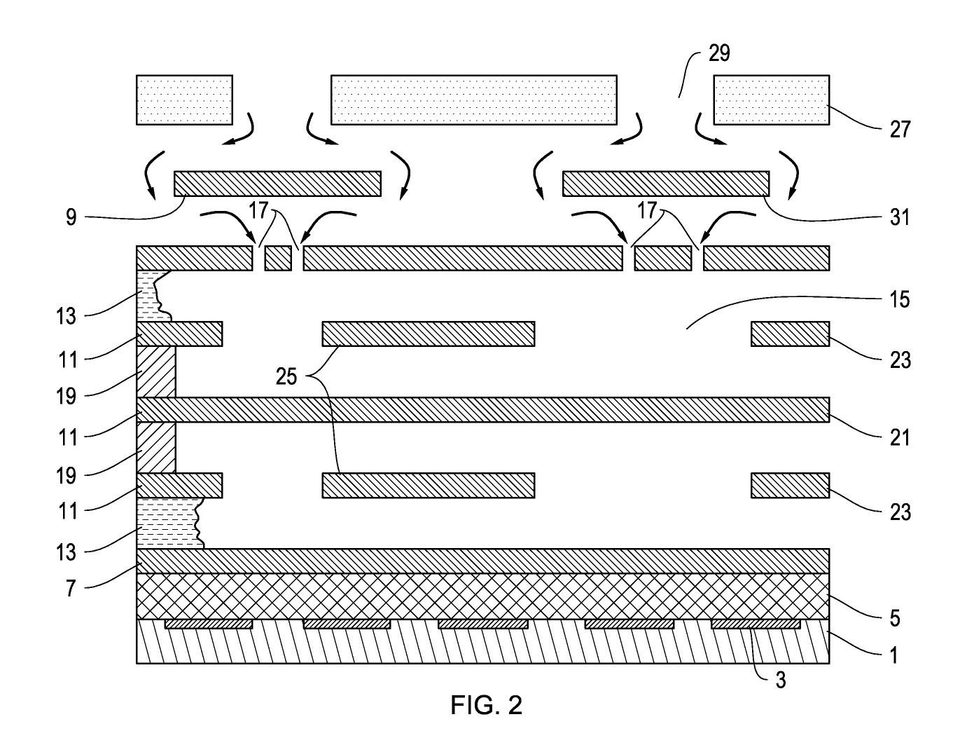

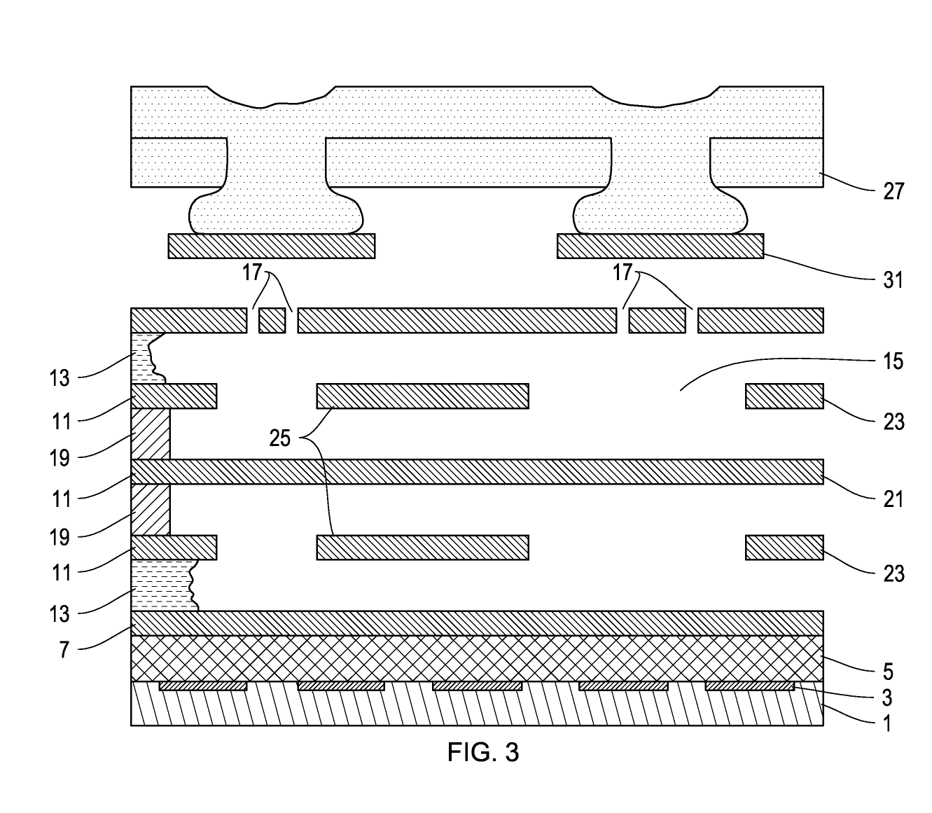

FIGS. 2 and 3 show another embodiment of the invention. In this case, the partial removal of stage b′) produces openings 29 that are arranged over plates of conductor material 31 belonging to the top layer of conductor material 9. Plates 31 do not prevent the HF attack. The HF may move around them, as shown diagrammatically in FIG. 2 by the arrows. However, plates 31 may be useful during the stage of producing a new sealing layer, because the new sealing layer passes through opening 29 and is deposited on plate 31 until it fills, at least partially, the hollow space between each opening 29 and its corresponding plate 31 (see FIG. 3). Therefore the arrangement of these plates 31 facing openings 29 facilitates the subsequent stage of producing a new sealing layer. Including said plates 31 is independent of using holes 17. In some embodiments, only plates 31 may be used, omitting the layer of conductor material that includes holes 17.

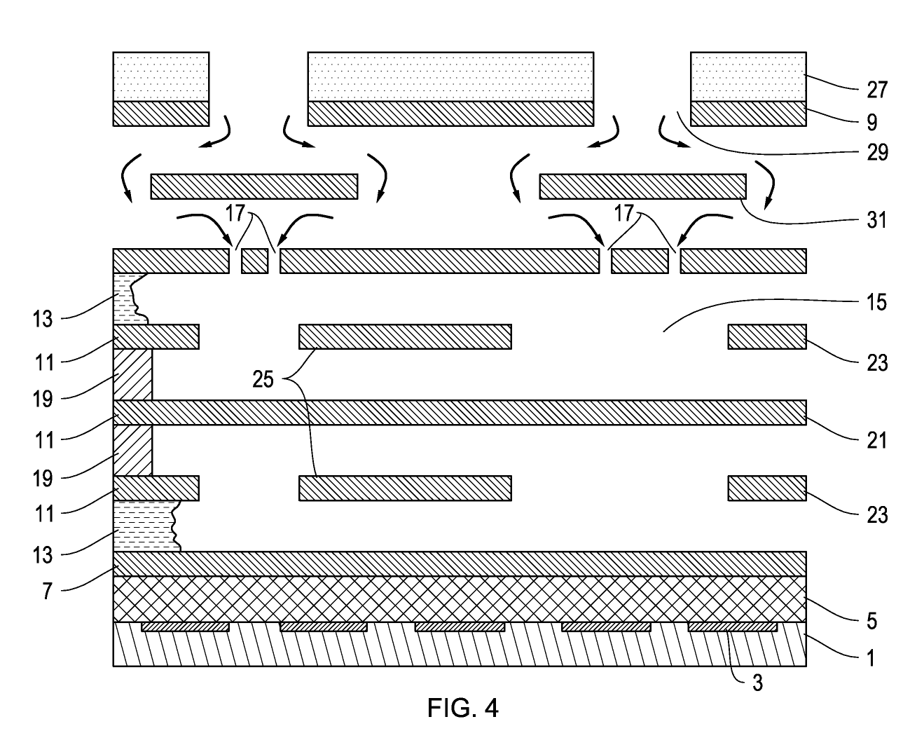

FIG. 4 shows another embodiment of the invention, similar to that in FIGS. 2 and 3. In this embodiment, passivation layer 27 rests directly on the top layer of conductor material 9, and plates 31 belong to an intermediate layer of conductor material. In effect, inserting a layer of dielectric material between the top layer of conductor material 9 and passivation layer 27 represents an additional stage of the conventional CMOS procedure, and it may be beneficial to remove it. However, generating a new sealing layer would take place as shown in FIG. 3.

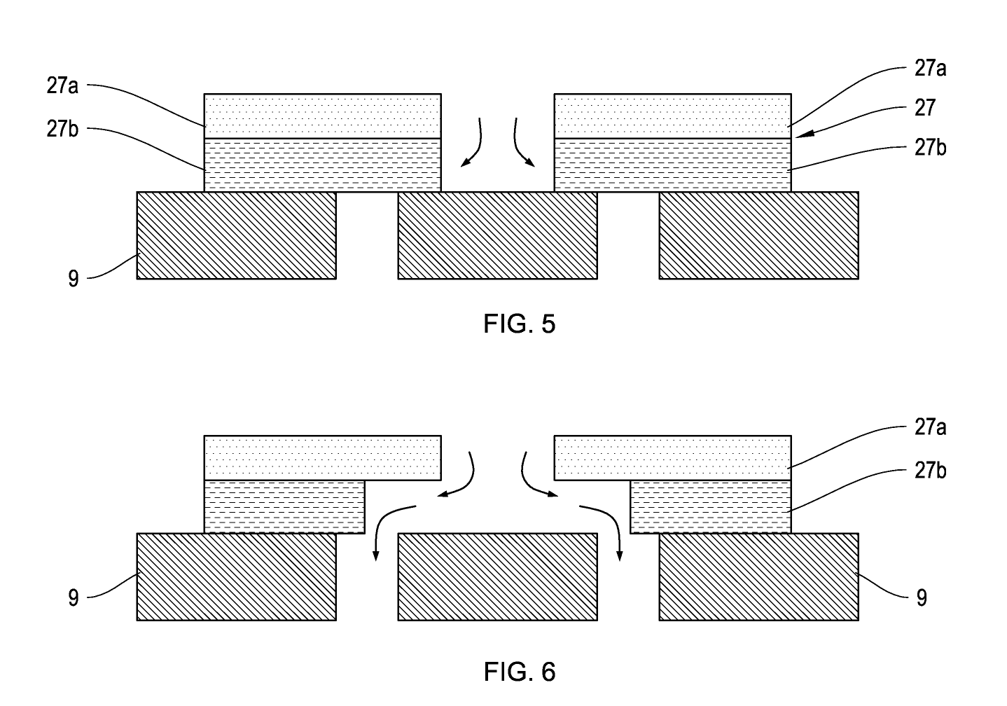

FIGS. 5 and 6 show another embodiment of the invention. In this embodiment, passivation layer 27 comprises a sublayer of silicon nitride 27a and a sublayer of silicon oxide 27b, and the sublayer of silicon oxide 27b is attacked by the HF. This allows the HF access to the layers of dielectric material, although the removal of the passivation layer has taken place in an area under which there is conductor material instead of dielectric material.

In some embodiments, the part of said top layer of conductor material (9) arranged on said MEMS has a plurality of holes, and the following layer of conductor material arranged under said top layer of conductor material (9) also has a plurality of holes that are not aligned with the holes in said top layer of conductor material. This allows said gaseous HF to run in zig-zag fashion in order to be able to reach the area of said MEMS. As a result, the subsequent sealing of the integrated circuit may be performed more easily, for example, by depositing another metallic layer (for example, Al), and/or depositing another passivation layer and/or WLCSP packaging.

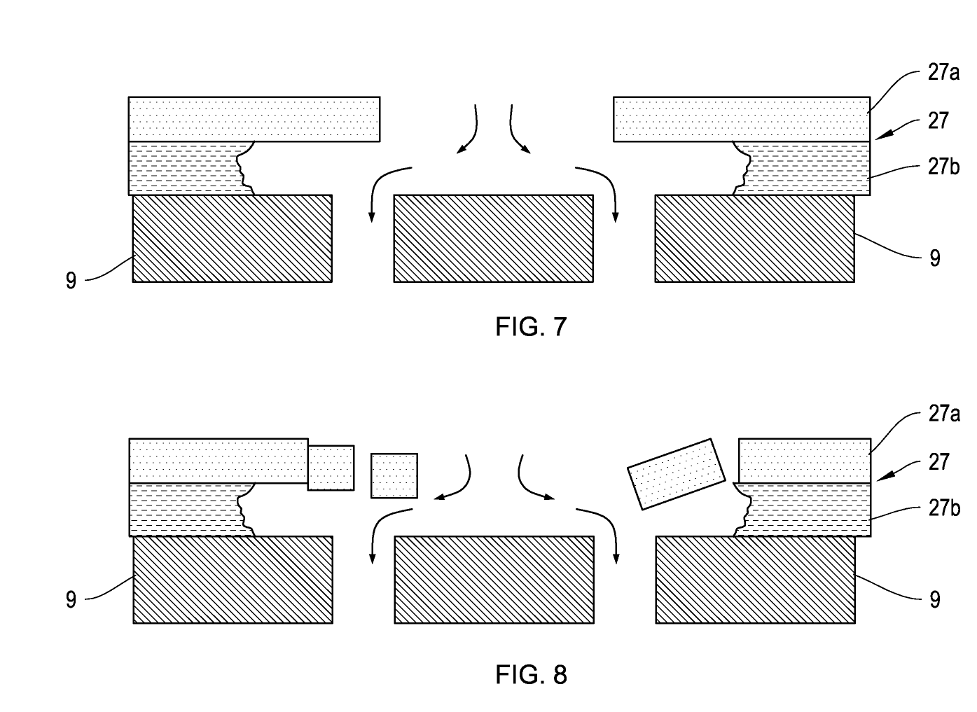

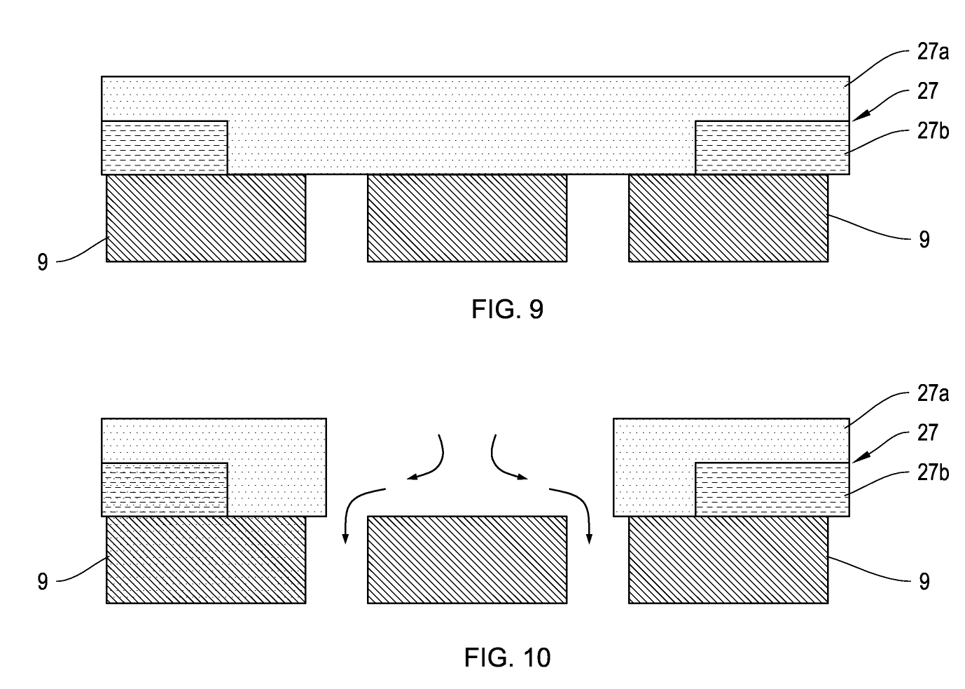

FIG. 7 shows, schematically, how the HF attacks the sublayer of silicon oxide 27b in a more pronounced way than the sublayer of silicon nitride 27a. This may cause a cantilever that can bend and/or break in an uncontrolled way (FIG. 8). To avoid this, the passivation layer may be made with two different masks, such that in some areas the silicon nitride sublayer 27a extends as far as the bottom layers (of conductor material 9 and/or dielectric material 13), as shown in FIG. 9. When the HF attacks passivation layer 27 in these areas, a “chimney” is formed that is completely wrapped in silicon nitride, whereby the HF does not come into direct contact with the silicon oxide (FIG. 10). In these embodiments, the silicon nitride sublayer 27a (which is approximately 300 nm) may be thicker than usual. The thickness may vary by CMOS process. In some embodiments, the silicon nitride sublayer 27a may be of a thickness between 500 nm and 700 nm. In some embodiments, the passivation may be planarized (e.g. with Chemical Mechanical Polishing (CMP)) to avoid cracks during and after the etching.

While the foregoing describes one or more MEMS devices arranged using one more an integrated circuit fabrication techniques that may be employed for various types of applications, the applications discussed below should not be considered as limited to this type of process. The foregoing is one type of process to implement the applications given below.

### Process Adjustments for CMOS Cu Processes

In some embodiments, the fabrication of a MEMS integrated circuit may require one or more adjustments in the manufacturing process flow. For example, adjustments may be needed when fabricating MEMS in an advanced CMOS process, e.g., CMOS copper (Cu) process. CMOS Cu processes typically exhibit feature sizes of 130 nm or lower. In some embodiments, a CMOS Cu process may exhibit a feature size of 65 nm or lower. Lower node processes may provide advantages such as smaller die area, lower cost, and lower power consumption, compared to higher node processes. Furthermore, MEMS and ASIC may be overlapped due to the large number of metal levels available, resulting in further savings in area.

In such a lower node (or feature size) process, the back-end layers of a MEMS device may be complex and highly customizable, with many different types of layers including, e.g., without limitation, silicon nitride sublayers. Some layers may have special dielectrics with low-k, while other layers may be conventional layers using silicon oxide (typically TEOS, HDP, or similar, or a combination of them). In another example, a silicon nitride sublayer may be found within a silicon oxide layer. A silicon nitride sublayer is typically not etched by vapor HF at the same rate as a silicon oxide sublayer, and may be used as an etching stop layer. A higher node aluminum (Al) process may not include a silicon nitride sublayer as an etching stop layer, requiring precise control of etching time or addition of a large metal plate to stop the etching. Therefore, addition of silicon nitride sublayers may be an advantage of a lower node Cu process when compared with a higher node Al process. Though vapor HF etching may be used with Cu, the introduction of silicon nitride sublayers may require adjustments to the CMOS process flow in order to perform etching using vapor HF.

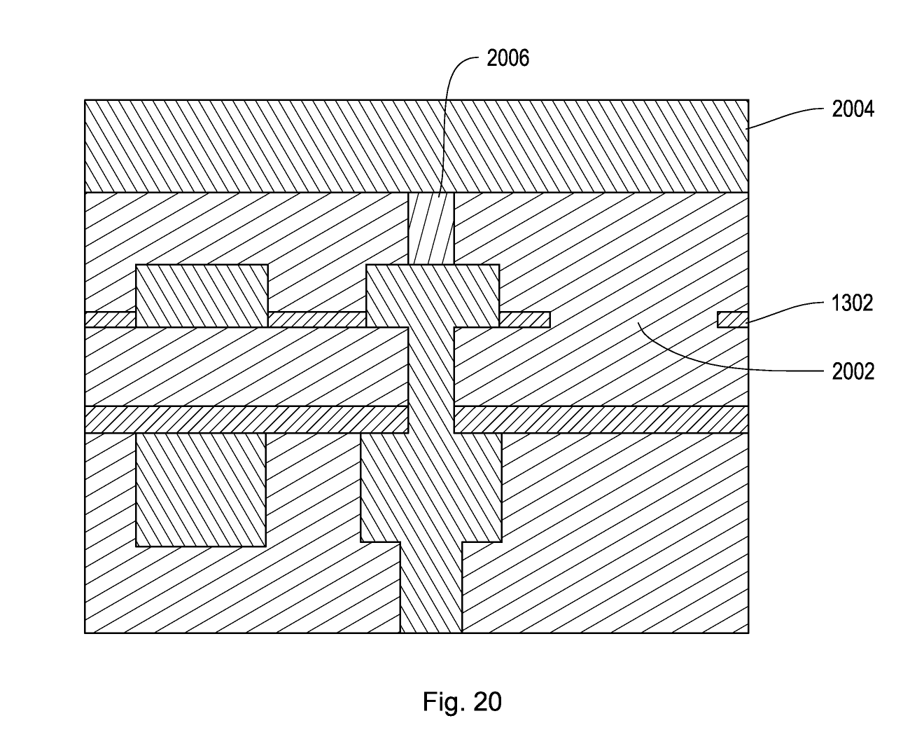

For example, if some area of a silicon nitride sublayer needs to be etched away, a standard etching step for the via/trench formation with a reduced etching time may be used to etch away the desired area. In another example, a DRV (Design Rule Violation) may be introduced into the CMOS process flow to etch the silicon nitride sublayer. The DRV may include drawing a via without metal on top. As a result of the DRV, the back-end layers may be fabricated with the desired area of the silicon nitride sublayer already removed (FIG. 20). Since there are typically several silicon nitride etching steps in a typical CMOS process flow, the proposed adjustments may be easily incorporated by a fabrication facility in its CMOS process flow without need for requalification.

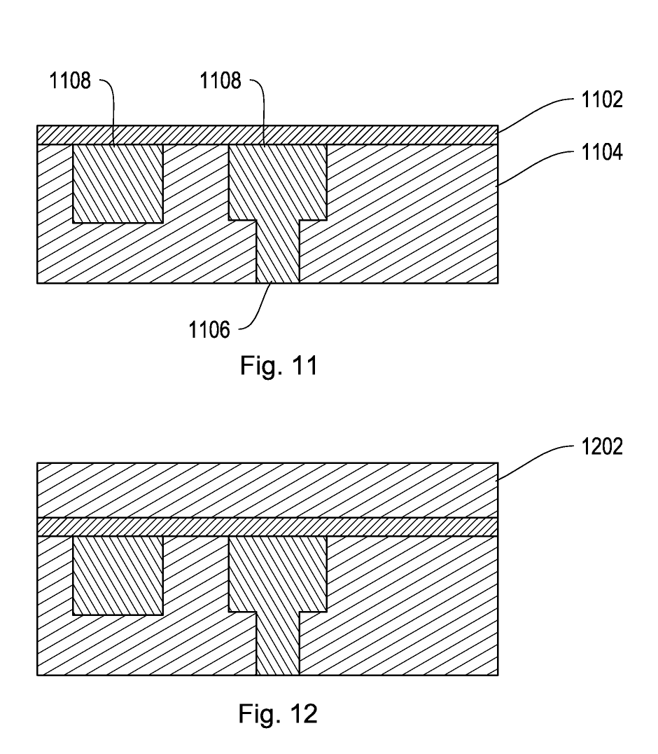

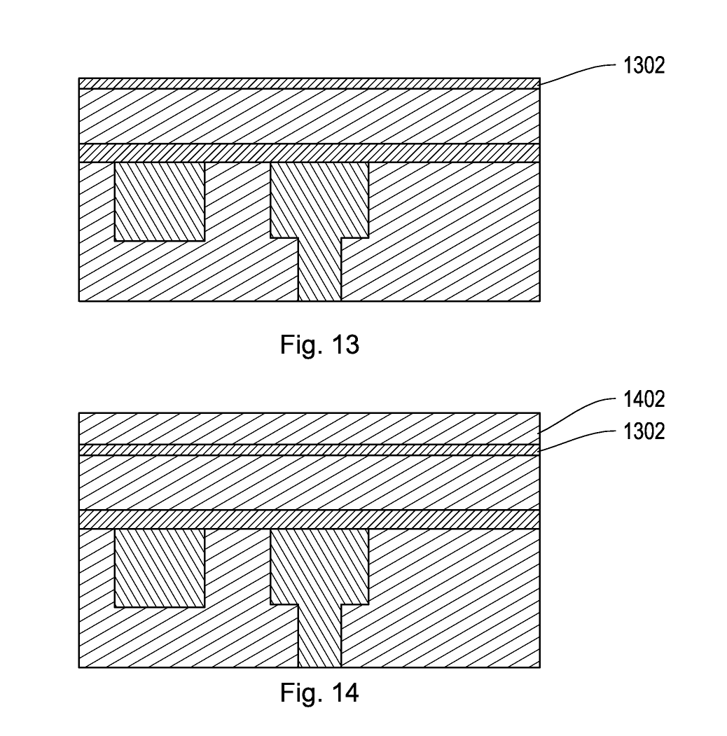

FIGS. 11-20 show an illustrative set of process flow steps for etching a silicon nitride layer by introducing a DRV into the CMOS process flow that draws a via without metal on top. For comparison, the figures also illustrate drawing a conventional via in the same substrate. FIG. 11 depicts a cross-section of backend layers in an integrated circuit after a first set of process flow steps. The layers may include various configurations of metal and dielectric layers. For example, the backend layers may be included in Inter Level Dielectric (ILD) layers of an integrated circuit. The ILD may also refer to an Inter Layer Dielectric (ILD) layer or an Inter Metal Dielectric (IMD) layer. Consequently, these back-end dielectric layers may be included at any position within the backend layers. The layers include Cu via 1106 and Cu lines 1108 embedded in silicon oxide sublayer 1104. Silicon nitride sublayer 1102 is disposed on silicon oxide sublayer 1104. In this illustrative process flow, an unmasked silicon oxide sublayer 1202 is then deposited on silicon nitride sublayer 1102 (FIG. 12). This is followed by deposition of an unmasked silicon nitride sublayer 1302 (FIG. 13) and another unmasked silicon oxide sublayer 1402 (FIG. 14).

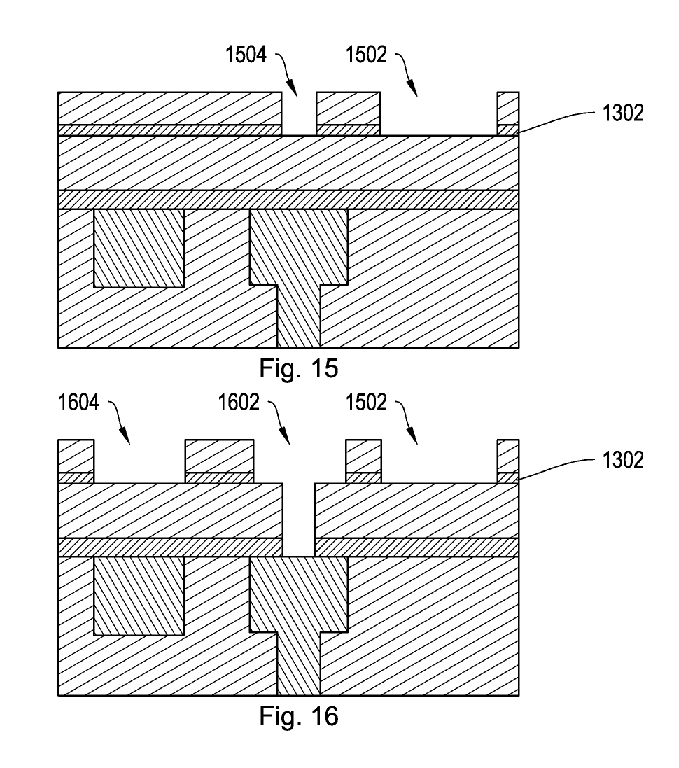

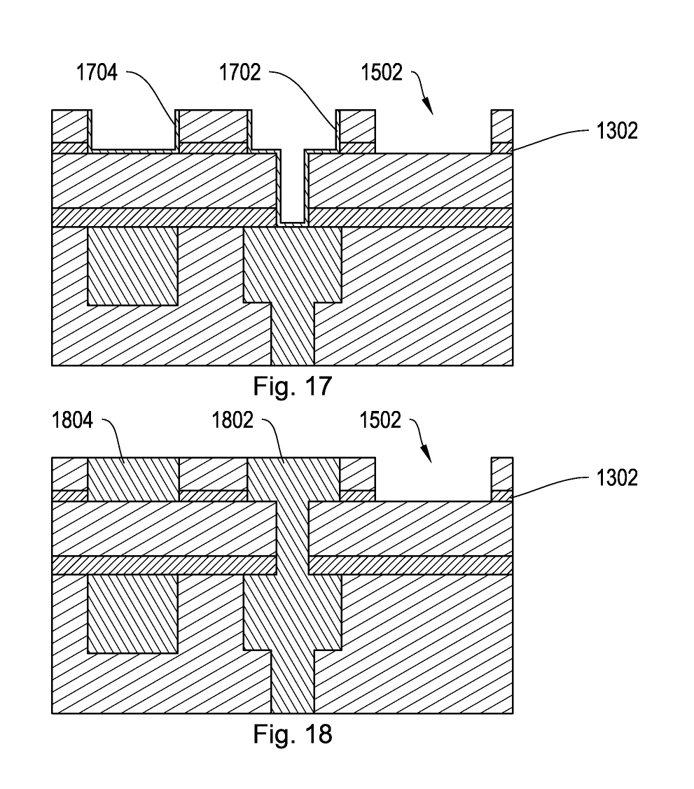

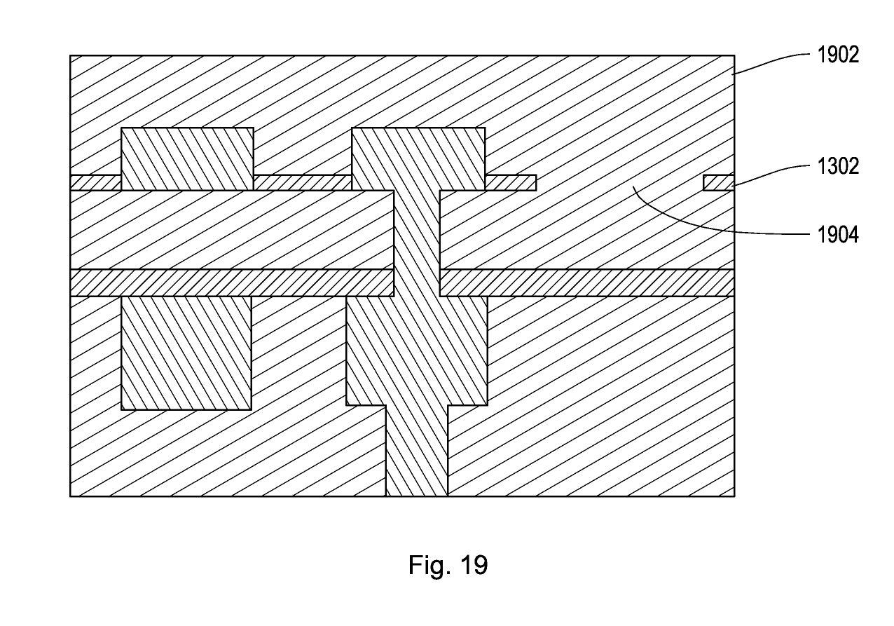

In this illustrative process flow, etching of a portion of silicon nitride sublayer 1302 is shown. In particular, a portion of sublayer 1302 is etched for fabrication of a metal via while another portion is etched and filled with silicon oxide. Silicon oxide sublayer 1402 is patterned using a via mask and etching such as, without limitation, isotropic etching, is applied to etch a portion of silicon oxide sublayer 1402 and the below silicon nitride sublayer 1302. Silicon nitride sublayer 1302 acts as an etch stopper and etching is completed when cavities 1502 and 1504 as shown are formed (FIG. 15). Subsequently, silicon oxide sublayer 1402 is again patterned using a metal mask and cavities 1602 and 1604 are formed using etching such as, without limitation, isotropic etching (FIG. 16). Silicon nitride sublayer 1302 again acts as an etch stopper. In this case, cavity 1602 is etched deeper into the layers because the upper portion of the cavity (1502) had already been etched in the previous step. Cavities 1602 and 1604 are seeded with Cu for electroplating to form layers 1702 and 1704 (FIG. 17) using the previous metal mask and Cu is subsequently grown in the cavities using electroplating to form lines 1802 and 1804 (FIG. 18). Furthermore, cavity 1502 is filled with silicon oxide by depositing silicon oxide sublayer 1902 and planarizing the layer with, e.g., chemical-mechanical polishing (CMP) (FIG. 19). Notice that silicon nitride sublayer 1302 now has a portion etched away as a result of drawing a via but filling it with silicon oxide in place of metal. This is facilitated by the metal mask not having any metal on top of the via. This may be considered to be a design rule violation (DRV), but may not require requalification of the fabrication process. This allows for application of conventional MEMS CMOS etching as described above, e.g., using vapor HF to form a hollow space in the interconnection layers.

In one embodiment, silicon oxide sublayer 1902 is further patterned with another via mask and the resulting holes filled with tungsten (W) plug 2006, followed by patterned aluminum (Al) deposition as a last metal layer. For example, this Al layer may be a last metal layer in a 130 nm or lower CMOS manufacturing process. Deposition of the Al layer may involve additional conventional CMOS process steps including, e.g., deposition of titanium (Ti) and titanium nitride (TiN) layers. If this layer is not the last metal layer, further silicon nitride layers may be deposited and selectively etched as described above. Note that the step(s) for etching silicon nitride layers do not break the standard CMOS process and may be implemented without need for requalification of the CMOS process. This is important for maintaining compatibility with MEMS CMOS fabrication described above with respect to FIGS. 1-10 (or as described in commonly-owned U.S. patent application Ser. No. 12/784,024 filed May 20, 2010, entitled “Methods and Systems for Fabrication of MEMS CMOS Devices”) as the manufacturing process is moved to lower nodes, e.g., a 130 nm or lower manufacturing process.

Applicant considers all operable combinations of the embodiments disclosed herein to be patentable subject matter. Those skilled in the art will know or be able to ascertain using no more than routine experimentation, many equivalents to the embodiments and practices described herein. Accordingly, it will be understood that the invention is not to be limited to the embodiments disclosed herein, but is to be understood from the following claims, which are to be interpreted as broadly as allowed under the law. It should also be noted that, while the following claims are arranged in a particular way such that certain claims depend from other claims, either directly or indirectly, any of the following claims may depend from any other of the following claims, either directly or indirectly to realize any one of the various embodiments of the invention.

What is claimed is:

1. A method for manufacturing an integrated circuit comprising:
producing layers that form one or more electrical and/or electronic elements on a semiconductor material substrate;
producing Inter Level Dielectric (ILD) layers above the layers forming the one or more electrical and/or electronic elements, wherein producing the ILD layers comprises:
depositing a first layer of etch stopper material;
depositing a second layer of dielectric material above and in contact with the first layer;
forming at least one track extending through the first and second layers; and
filling the at least one track with a non-metallic material.

2. The method of claim 1, further comprising forming at least one hollow space in the ILD layers by applying gaseous HF to at least a portion of the ILD layers including the at least one track.

3. The method of claim 1, wherein the at least one track includes a channel arranged to hold a metallic material for conducting electrical information to and from the one or more electrical and/or electronic elements.

4. The method of claim 1, wherein forming the at least one track includes etching the first and second layers.

5. The method of claim 1, wherein the etch stopper material includes silicon nitride.

6. The method of claim 1, wherein the dielectric material includes silicon oxide.

7. The method of claim 1, wherein the non-metallic material is capable of being etched by vapor HF.

8. The method of claim 7, wherein the non-metallic material includes silicon oxide.

9. The method of claim 1, wherein forming the at least one track includes forming the at least one track above a via space that is empty or holds metal.

10. The method of claim 1, wherein filling the at least one track with a non-metallic material is a result of a CMOS design rule violation.

11. The method of claim 1, wherein the one or more electrical and/or electronic elements have a feature size of 130 nm or lower.

12. The method of claim 1, wherein the integrated circuit is included in one of a handheld device, a mobile phone, a portable computing device, a computer tablet, and a wireless computing device.

13. The method of claim 1, wherein the integrated circuit is included in a motion sensor.

14. The method of claim 2, wherein at least a portion of a micro-electro-mechanical system (MEMS) is arranged in the integrated circuit.

15. The method of claim 14, wherein the portion of the MEMS is arranged in the hollow space in the ILD layers.

16. The method of claim 1, wherein the first and second layers are etched at substantially the same time using isotropic etching.

17. The method of claim 1, wherein the integrated circuit is manufactured using a CMOS manufacturing process.

18. The method of claim 1, wherein filling the at least one track with a non-metallic material is performed without requalification of a conventional CMOS manufacturing process.

19. The method of claim 14, wherein the MEMS comprises a conductor element including a movable part.

20. The method of claim 19, wherein the MEMS comprises at least two capacitor plates arranged to produce electrostatic fields over the movable part that are capable of moving the movable part.

21. The method of claim 19, wherein the MEMS operates as a relay, the MEMS comprising at least two contact points in an electric circuit arranged to allow the movable part to be in contact simultaneously with both contact points.

22. The method of claim 14, wherein the MEMS comprises a device including at least one of an electrical relay, accelerometer, gyroscope, inclinometer, Coriolis force detector, pressure sensor, microphone, flow rate sensor, temperature sensor, gas sensor, magnetic field sensor, electro-optical device, optical switching matrix, image projector device, analogue connection matrix, electromagnetic signal emission and/or reception device, power supply, DC/DC converter, AC/DC converter, DC/AC converter, A/D converter, D/A converter, and power amplifier.

23. The method of claim 19, wherein the at least one track defines one or more lateral edges of the first layer that are not in contact with a metallic material.

24. The method of claim 23, wherein the metallic material includes at least one of copper and aluminum.

25. A chip comprising an integrated circuit, said integrated circuit comprising:
one or more layers forming electrical and/or electronic elements on a semiconductor material substrate
one or more Inter Level Dielectric (ILD) layers above the layers forming the one or more electrical and/or electronic elements, the ILD layers comprising:
a first layer of etch stopper material;
a second layer of dielectric material above and in contact with the first layer;
at least one track extending through the first and second layers, wherein the at least one track is filled with a non-metallic material.

26. A method for manufacturing an integrated circuit comprising:
producing layers that form one or more electrical and/or electronic elements on a semiconductor material substrate;
producing Inter Level Dielectric (ILD) layers above the layers forming the one or more electrical and/or electronic elements, wherein producing the ILD layers comprises:
depositing a first layer of etch stopper material;
depositing a second layer of dielectric material above and in contact with the first layer;
forming a track extending through the first and second layers, the track defining one or more lateral edges of the first layer, wherein the one or more lateral edges are not in contact with a metallic material.

27. The method of claim 26, filling the track with a non-metallic material.

28. The method of claim 27, wherein the non-metallic material includes silicon oxide.

29. The method of claim 26, wherein forming the track includes forming the track above a via space that is empty or holds metal.

30. The method of claim 26, wherein filling the track with a non-metallic material is a result of a CMOS design rule violation.

31. The method of claim 26, wherein the metallic material includes at least one of copper and aluminum.

32. The method of claim 26, wherein forming the track includes etching the first and second layers.

33. The method of claim 26, wherein the etch stopper material includes silicon nitride.

34. The method of claim 26, wherein the dielectric material includes silicon oxide.

35. The method of claim 26, wherein the non-metallic material is capable of being etched by vapor HF.

36. The method of claim 26, wherein the one or more electrical and/or electronic elements have a feature size of 130 nm or lower.

37. The method of claim 26, wherein the integrated circuit is included in a handheld device, a mobile phone, a portable computing device, a computer tablet, and a wireless computing device.

38. The method of claim 26, wherein the integrated circuit is included in a motion sensor.

39. The method of claim 26, wherein at least a portion of a micro-electro-mechanical system (MEMS) is arranged in the integrated circuit.

40. A chip comprising an integrated circuit, said integrated circuit comprising:
one or more layers that form electrical and/or electronic elements on a semiconductor material substrate;
one or more Inter Level Dielectric (ILD) layers above the layers forming the one or more electrical and/or electronic elements, the ILD layers comprising:
a first layer of etch stopper material;
a second layer of dielectric material above and in contact with the first layer;
a first track extending through the first and second layers, the first track defining one or more lateral edges of the first layer, wherein the one or more lateral edges are not in contact with a metallic material.
